(19) United States
(12) Patent Application Publication
(10) Pub. No.: US 2016/0351154 A1
(43) Pub. Date: Dec. 1, 2016

(54) CLOCK SIGNAL GENERATING CIRCUIT, GATE DRIVING CIRCUIT, DISPLAY PANEL AND DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Fei XU, Beijing (CN); Zhen ZHANG, Beijing (CN); Zhiwei ZHANG, Beijing (CN)

(21) Appl. No.: 15/097,480

(22) Filed: Apr. 13, 2016

(30) Foreign Application Priority Data
May 25, 2015 (CN) 201510270561.8

(51) Int. Cl. G09G 3/36; G06F 1/06; G09G 3/20; H03K 3/013; G11C 19/28

(52) U.S. Cl. CPC G09G 3/3677; H03K 3/013; G11C 19/287; G09G 3/2085; G06F 1/06; G09G 2310/08; G09G 2310/0286; G09G 2300/08

(57) ABSTRACT

A clock signal generating circuit, a gate driving circuit, a display panel and a display device are disclosed. A first clock signal terminal inputs a first clock signal to a selection module. A second clock signal terminal inputs a second clock signal to the selection module. The selection module couples a high level signal input terminal to an output terminal or disconnects the high level signal input terminal from the output terminal according to the first clock signal, and couples a low level signal input terminal to the output terminal or disconnects the low level signal input terminal from the output terminal according to the second clock signal. The selection module couples the high level signal input terminal and the low level signal input terminal alternately to the output terminal, so that the output terminal outputs a target clock signal.

### CROSS-REFERENCE TO RELATED APPLICATION

This application claims priority to Chinese Patent Application No. 201510270561.8, filed on May 25, 2015, the contents of which are incorporated by reference in the entirety.

### FIELD OF THE INVENTION

The present invention relates to the field of display technology, and particularly relates to a clock signal generating circuit, agate driving circuit, a display panel and a display device.

### BACKGROUND OF THE INVENTION

A thin film transistor liquid crystal display (hereinafter referred to as TFT LCD) usually realizes display by means of progressive scanning. The progressive scanning is performed by a gate driving circuit and a source driving circuit. Specifically, the gate driving circuit makes a clock signal be converted by a shift register and then applies the converted clock signals to a plurality of gate lines of a display panel in sequence, so as to drive the thin film transistors of a plurality of rows of pixels to be turned on in sequence. In addition, the source driving circuit provides a corresponding data signal for each pixel in the row of pixels that are turned on, so as to realize display of each row of pixels and progressive display of the plurality of rows of pixels.

In an existing TFT LCD, a clock signal is applied to a plurality of rows of pixels and has a heavy load. Therefore, during display of each frame of image, as the number of the rows of pixels that are scanned by the gate driving circuit increases, the clock signal will gradually attenuate under the influence of resistance (a signal line has resistance) and capacitance (the shift register is equivalent to a capacitor) in a signal transmission line, thereby being distorted. Particularly, in a TEL LCD having relatively high resolution, since there are many rows of pixels, when several rows of pixels at a far end are scanned, the distortion of the clock signal may even cause insufficient Charge and thus the clock signal may fail to drive the several rows of pixels to he turned on. For example, as shown in FIG. 1, when the gate driving circuit scans the n^{th} row of pixels, the clock signal is significantly distorted, which is apt to cause insufficient charge when the thin film transistors in the n^{th} row of pixels are driven to be turned on, so that the thin film transistors in said row of pixels cannot be turned on and display of said row of pixels cannot be realized.

SUMMARY OF THE INVENTION

In order to solve at least the foregoing technical problem existing in the prior art, the embodiments of the present invention provide a clock signal generating circuit, a gate driving circuit, a display panel and a display device, which can reduce distortion of a target clock signal so as to guarantee display effect of a display panel.

An embodiment of the present invention provides a clock signal generating circuit, comprising a selection module, a high level signal input terminal, a low level signal input terminal, a first clock signal terminal, a second clock signal terminal and an output terminal, wherein the first clock signal terminal inputs a first clock signal to the selection module; the second clock signal terminal inputs a second clock signal to the selection module; the selection module couples the high level signal input terminal to the output terminal or disconnects the high level signal input terminal from the output terminal according to the first clock signal, and couples the low level signal input terminal to the output terminal or disconnects the low level signal input terminal from the output terminal according to the second clock signal; and the selection module couples the high level signal input terminal and the low level signal input terminal alternately to the output terminal, so that the output terminal outputs a target clock signal.

The selection module may comprise a first transistor and a second transistor. A gate of the first transistor is connected with the first clock signal terminal, a source of the first transistor is connected with the high level signal input terminal, and a drain of the first transistor is connected with the output terminal. A gate of the second transistor is connected with the second clock signal terminal, a source of the second transistor is connected with the low level signal input terminal, and a drain of the second transistor is connected with the output terminal.

A high level signal inputted from the high level signal input terminal and a low level signal inputted from the low level signal input terminal may be direct current signals.

At any time, the first clock signal inputted from the first clock signal terminal and the second clock signal inputted from the second clock signal terminal may have opposite levels. The target clock signal may have a waveform the same as that of the first clock signal or the second clock signal.

An embodiment of the present invention further provides a gate driving circuit, comprising the foregoing clock signal generating circuit for providing the target clock signal, and multiple stages of shift registers.

The gate driving circuit may comprise a plurality of said clock signal generating circuits, each of which is connected to a part of the shift registers.

The number of the clock signal generating circuits may be two, and the two clock signal generating circuits are respectively located at an upper end and a lower end of one side of a display panel on which the shift registers are disposed, and are respectively connected with the multiple stages of shift registers in an upper part of the display panel and the multiple stages of shift registers in a lower part of the display panel.

Two ends of every row of pixels on the display panel may be connected with one stage of shift registers on corresponding two sides, respectively.

A plurality of the clock signal generating circuits may be provided on each of two opposite sides of the display panel on which the multiple stages of shift registers are provided, and each clock signal generating circuit is connected with a part of the shift registers on a corresponding side.

The number of the clock signal generating circuits may be four, the four clock signal generating circuits are respectively provided in four corners of the display panel, each of the clock signal generating circuits which are located in the lower part is connected with the multiple stages of shift registers which are located in a lower part of a corresponding side of the display panel, and each of the clock signal generating circuits which are located in the upper part is connected with the multiple stages of shift registers which are located in an upper part of a corresponding side of the display panel.

An embodiment of the present invention further provides a display panel, comprising the foregoing gate driving circuit.

An embodiment of the present invention further provides a display device, comprising the foregoing display panel.

In the clock signal generating circuit provided by the embodiment of the present invention, the selection module couples the high level signal input terminal and the low level signal input terminal alternately to the output terminal under the control of the first clock signal terminal and the second clock signal terminal, so that a signal outputted from the output terminal is the target clock signal. In such process, the load of the first clock signal outputted from the first clock signal terminal and the second clock signal outputted from the second clock signal terminal is merely the selection module, and said load is remarkably small in view of the prior art, so that the distortion of the first clock signal and the second clock signal is relatively small, thereby enabling the high level signal input terminal and the low level signal input terminal to be accurately coupled to or disconnected from the output terminal at a preset time, that is, making an output of the target clock signal at a corresponding time be equal to a preset value, that is to say, the target clock signal is accurate. In such a way, when the high level signal inputted from the high level signal input terminal and the low level signal inputted from the low level signal input terminal are direct current signals or other types of signals which are slightly influenced by the load, and the gate driving circuit scans a gate line at a far end, insufficient charge due to large distortion of the clock signal inputted to the shift register connected with said gate line may be avoided, and consequent failure to drive the thin film transistors connected with said gate line to be turned on may be avoided, so that display effect of a row of pixels at the far end of the display panel can be guaranteed.

The gate driving circuit, the display panel and the display device provided by the embodiments of the present invention adopt the foregoing clock signal generating circuit, and may avoid insufficient charge due to large distortion of a clock signal inputted to a shift register connected with a gate line, and avoid consequent failure to drive the thin film transistors connected with said gate line to be turned on, so that display effect of a row of pixels at a far end of the display panel can be guaranteed.

### BRIEF DESCRIPTION OF THE DRAWINGS

The drawings constitute a part of the specification, and are used for providing further understanding of the present invention and for explaining the present invention in conjunction with the following specific embodiment, but do not limit the present invention. In the drawings:

FIG. 1 is a schematic diagram illustrating distortion of a clock signal in the prior art;

FIG. 2 is a schematic diagram of a clock signal generating circuit according to an embodiment of the present invention;

FIG. 3 is a circuit diagram of the clock signal generating circuit of FIG. 2;

FIG. 4 is a timing diagram of signals of the clock signal generating circuit of FIG. 3;

FIG. 5 is a schematic diagram of a gate driving circuit comprising a plurality of clock signal generating circuits; and

FIG. 6 is a schematic diagram of a gate driving circuit for double-side driving comprising a plurality of clock signal generating circuits.

### DETAILED DESCRIPTION OF THE EMBODIMENTS

Specific implementations of the present invention will be described in detail below with reference to the drawings. It should be understood that the specific implementations described here are merely used for illustrating and explaining the present invention, but not for limiting the present invention.

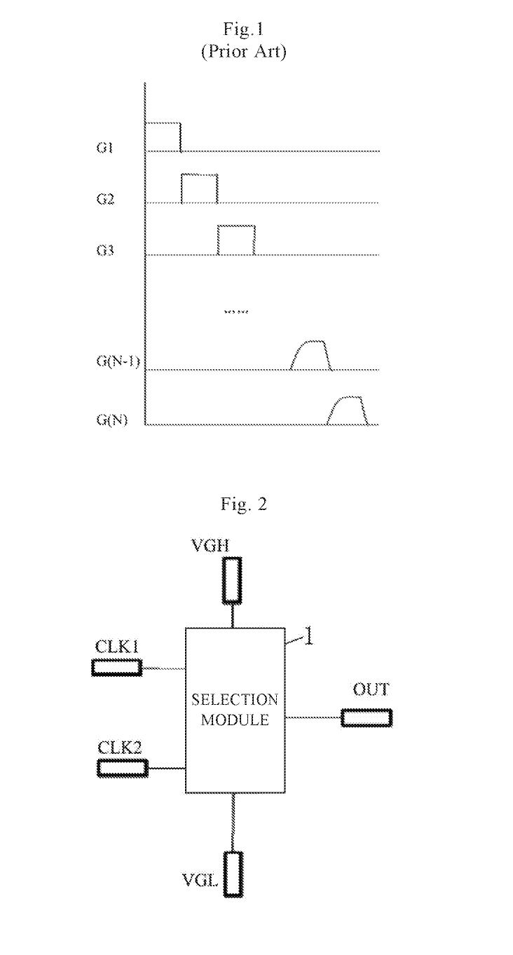

FIG. 2 is a schematic diagram of a clock signal generating circuit according to an embodiment of the present invention. As shown in FIG. 2, the clock signal generating circuit comprises a selection module 1, a high level signal input terminal VGH, a low level signal input terminal VGL, a first clock signal terminal CLK1, a second clock signal terminal CLK2 and an output terminal OUT. The first clock signal terminal CLK1 inputs a first clock signal to the selection module 1. The second clock signal terminal CLK2 inputs a second clock signal to the selection module 1. The selection module 1 couples the high level signal input terminal VGH to the output terminal OUT or disconnects the high level signal input terminal VGH from the output terminal OUT according to the first clock signal, and couples the low level signal input terminal VGL to the output terminal OUT or disconnects the low level signal input terminal VGL from the output terminal OUT according to the second clock signal. The selection module 1 couples the high level signal input terminal VGH and the low level signal input terminal VGL alternately to the output terminal OUT, so that the output terminal OUT outputs a target clock signal.

The selection module 1 couples the high level signal input terminal VGH and the low level signal input terminal VGL alternately to the output terminal OUT under the control of the first clock signal terminal CLK1 and the second clock signal terminal CLK2, so that a signal outputted from the output terminal OUT is the target clock signal. It can be seen that the load of the first clock signal outputted from the first clock signal terminal CLK1 and the second clock signal outputted from the second clock signal terminal CLK2 is merely the selection module 1, instead of a plurality of gate lines in the prior art. In comparison with the prior art, the first clock signal and the second clock signal have a small load in this embodiment and thus have smaller distortion, thereby enabling the high level signal input terminal VGH and the low level signal input terminal VGL to be accurately coupled to or disconnected from the output terminal OUT at a preset time, that is, making an output of the target clock signal at a corresponding time be equal to a preset value, that is to say, the target clock signal is accurate. In such a way, when the high level signal inputted from the high level signal input terminal VGH and the low level signal inputted from the low level signal input terminal VGL are direct current signals and the like, and a gate driving circuit scans a gate line at a far end, insufficient charge due to large distortion of a clock signal inputted to a shift register connected with said gate line may be avoided, and failure to drive the thin film transistors connected with said gate line to be turned on may be avoided, so that display effect of a pixel row at the far end of a display panel can be guaranteed.

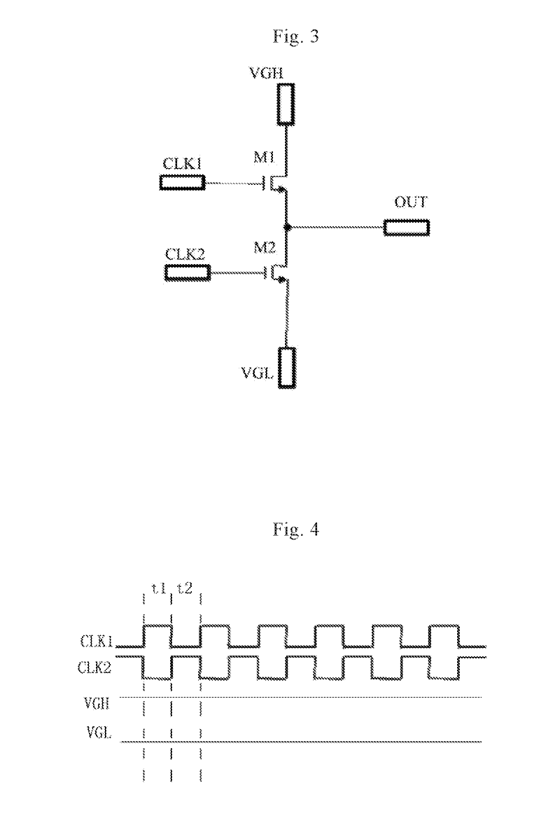

As shown in FIG. 3, the selection module 1 comprises a first transistor M1 and a second transistor M2, A gate of the first transistor M1 is connected with the first clock signal terminal CLK1 a source of the first transistor M1 is connected with the high level signal input terminal VGH, and a drain of the first transistor M1 is connected with the output terminal OUT. A gate of the second transistor M2 is connected with the second clock signal terminal CLK2, a source of the second transistor M2 is connected with the low level signal input terminal VGL, and a drain of the second transistor M2 is connected with the output terminal OUT. For example, the first transistor M1 and the second transistor M2 are N-type transistors, that is, are turned on when the gates thereof are applied with a high level signal and are turned off when the gates thereof are applied with a low level signal.

In this embodiment, for example, the high level signal inputted from the high level signal input terminal VGH and the low level signal inputted from the low level signal input terminal VGL are direct current signals, so that the distortion of the target clock signal due to heavy load becomes small, thereby avoiding the foregoing insufficient charge due to the distortion and consequent failure to drive the thin film transistors connected with a gate line at a far end to be turned on.

FIG. 4 is a timing diagram of signals of the clock signal generating circuit of FIG. 3. The principle and process of generating a target clock signal by the clock signal generating circuit provided by this embodiment will be described in detail below with reference to the timing diagram of FIG. 4.

In a first stage, that is, in a time period t1, a high level signal is inputted from the first clock signal terminal CLK1, a low level signal is inputted from the second clock signal terminal CLK2, another high level signal is inputted from the high level signal input terminal VGH, and another low level signal is inputted from the low level signal input terminal VGL.

In such case, the first transistor M1 is turned on, the second transistor M2 is turned off, and the high level signal input terminal VGH is coupled to the output terminal OUT, so that the output terminal OUT outputs a high level signal.

In a second stage, that is, in a time period t2, a low level signal is inputted from the first clock signal terminal CLK1, a high level signal is inputted from the second clock signal terminal CLK2, another high level signal is inputted from the high level signal input terminal VGH, and another low level signal is inputted from the low level signal input terminal VGL. In such case, the first transistor M1 is turned off, the second transistor M2 is turned on, and he low level signal input terminal VGL is coupled to the output terminal OUT, so that the output terminal OUT outputs a low level signal.

In following stages, the first clock signal, the second clock signal, the high level signal and the low level signal have the levels the same as those in the time period t1 and the time period t2 repeatedly, so that the output terminal OUT accordingly outputs the signal waveforms the same as those outputted in the time period t1 and the time period t2 repeatedly, that is, the target clock signal has the levels the same as those outputted in the time period t1 and the time period t2 repeatedly, the processes of the repetitions are the same as those in the time period t1 and the time period t2 and thus will not be described herein.

Specifically, at any time, the first clock signal inputted from the first clock signal terminal CLK1 and the second clock signal inputted from the second clock signal terminal CLK2 have opposite levels, so that the high level signal input terminal VGH and the low level signal input terminal VGL are coupled alternately to the output terminal OUT, thereby enabling the output terminal OUT to output a high level signal and a low level signal alternately.

For example, the waveform of the target clock signal is the same as that of the first clock signal, or is the same as that of the second clock signal. In addition, the first clock signal terminal CLK1 and the second clock signal terminal CLK2 may adopt clock signal terminals in the prior art, so that the target clock signal outputted from the output terminal OUT is similar to a clock signal in the prior art, but the target clock signal in the embodiment of the present invention has, in comparison with the prior art, less distortion.

In the clock signal generating circuit provided by the embodiment of the present invention, the selection module 1 couples the high level signal input terminal VGH and the low level signal input terminal VGL alternately to the output terminal OUT under the control of the first clock signal terminal CLK1 and the second clock signal terminal CLK2, so that a signal outputted from the output terminal OUT is the target clock signal. In such process, the load of the first clock signal outputted from the first clock signal terminal CLK1 and the second clock signal outputted from the second clock signal terminal CLK2 is merely the selection module 1, and said load is remarkably small in view of the prior art, so that the distortion of the first clock signal and the second clock signal is relatively small, thereby enabling the high level signal input terminal VGH and the low level signal input terminal VGL to be accurately coupled to or disconnected from the output terminal OUT at a preset time, that is, making an output of the target clock signal at a corresponding time be equal to a preset value, that is to say, the target clock signal is accurate. In such a way, when the high level signal inputted from the high level signal input terminal VGH and the low level signal inputted from the low level signal input terminal VGL are direct current signals and the like, and a gate driving circuit scans a gate line at a far end, insufficient charge due to large distortion of the clock signal inputted to a shift register connected with said gate line may be avoided, and failure to drive the thin film transistors connected with said gate line to be turned on may be avoided, so that display effect of a pixel row at the far end of a display panel can be guaranteed.

An embodiment of the present invention further provides a gate driving circuit. In this embodiment, the gate driving circuit comprises the clock signal generating circuit provided by the foregoing embodiment of the present invention, and the clock signal generating circuit provides the target clock signal.

The gate driving circuit provided by the embodiment of the present invention adopts the clock signal generating circuit provided by the foregoing embodiment of the present invention, and may avoid insufficient charge due to large distortion of a clock signal inputted to a shift register connected with a gate line and failure to drive the thin film transistors connected with said gate line to be turned on, so that display effect of a pixel row at a far end of a display panel can be guaranteed.

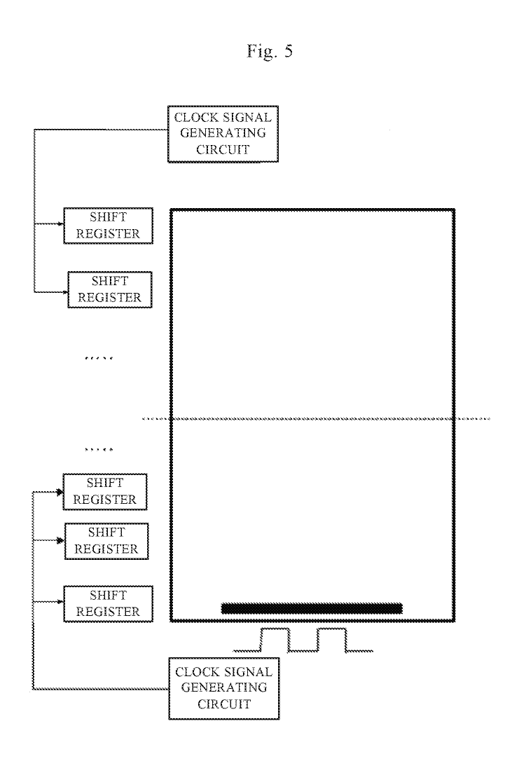

Specifically, as shown in FIG. 5, the gate driving circuit comprises multiple stages of shift registers and a plurality of the clock signal generating circuits, each of the clock signal generating circuits is connected with a part of the shift registers. In comparison with a technical solution in the prior art that a gate driving circuit comprises only one clock signal generating circuit, each clock signal generating circuit only needs to input the target clock signal to a part of the shift registers in this embodiment, which makes the target clock signal inputted from each clock signal generating circuit to a shift register at a far end have less distortion, so as to further avoid insufficient charge due to large distortion of a clock signal inputted to a shift register connected with a gate line, and avoid failure to drive the thin film transistors connected with said gate line to be turned on, thereby guaranteeing display effect of each pixel row of a display panel.

For example, as shown in FIG. 5, the number of the clock signal generating circuits may be two, and the two clock signal generating circuits are respectively located at an upper end and a lower end of one side of a display panel on which the shift registers are disposed, and are respectively connected with the multiple stages of shift registers in an upper part of the display panel and the multiple stages of shift registers in a lower part of the display panel.

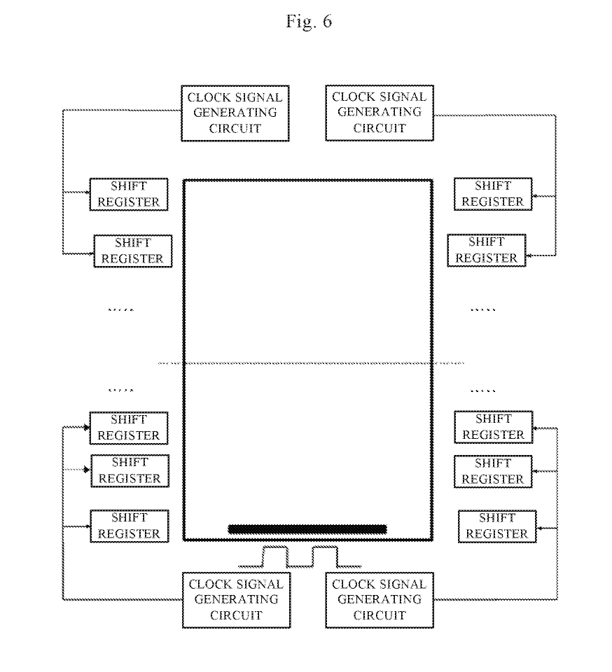

In the embodiment of the present invention, as shown in FIG. 6, the gate driving circuit comprises multiple stages of shift registers, and each of two ends of every row of pixels on the display panel is connected with one stage of the shift register. In such case, when the gate driving circuit drives each row of pixels to be turned on, the shift registers located on two sides of said row of pixels simultaneously input driving signals to said row of pixels, that is, so-called “double-sided” driving is performed, so as to accelerate the speed of driving the thin film transistors of each row of pixels to be turned on, thereby reducing the time for scanning a frame of image and increasing refresh rate. In addition, a plurality of the clock signal generating circuits are provided on each of two opposite sides of the display panel on which the multiple stages of shift registers are provided, and each clock signal generating circuit is connected with a part of the shift registers on the side where the clock signal generating circuit is located. Similar to the foregoing description, each clock signal generating circuit only needs to input the target clock signal to a part of the shift registers in this embodiment, which makes the target clock signal inputted from each clock signal generating circuit to a shift register at a far end have less distortion, so as to further avoid insufficient charge due to large distortion of a clock signal inputted to a shift register connected with a gate line, and avoid failure to drive the thin film transistors connected with said gate line to be turned on, thereby guaranteeing display effect of each pixel row of a display panel.

For example, as shown in FIG. 6, the number of the clock signal generating circuits is four, the four clock signal generating circuits are respectively provided in four corners of the display panel, each of the clock signal generating circuits located in the lower part is connected with the multiple stages of shift registers located in a lower part of a corresponding side of the display panel, and each of the clock signal generating circuits located in the upper part is connected with the multiple stages of shift registers located in an upper part of a corresponding side of the display panel.

An embodiment of the present invention further provides a display panel. In this embodiment, the display panel comprises the gate driving circuit provided by the foregoing embodiment of the present invention.

The display panel provided by the embodiment of the present invention adopts the gate driving circuit provided by the foregoing embodiment of the present invention, and may avoid insufficient charge due to large distortion of a clock signal inputted to a shift register connected with a gate line, and avoid failure to drive the thin film transistors connected with said gate line to be turned, so that display effect of a pixel row at a far end of a display panel can be guaranteed.

The invention further provides an embodiment of a display device. In this embodiment, the display device comprises the display panel provided by the foregoing embodiment of the present invention.

The display device provided by the embodiment of the present invention adopts the display panel provided by the foregoing embodiment of the present invention, and may avoid insufficient charge due to large distortion of a clock signal inputted to a shift register connected with agate line, and avoid failure to drive the thin film transistors connected with said gate line to be turned, so that display effect of a pixel row at a far end of a display panel can be guaranteed.

It should be understood that the foregoing implementations are merely exemplary implementations adopted for describing the principle of the present invention, but the present invention is not limited thereto. Those of ordinary skill in the art may make various variations and improvements without departing from the spirit and essence of the present invention, and these variations and improvements shall be considered to fall within the protection scope of the present invention.

What is claimed is:

1. A clock signal generating circuit, comprising a selection module, a high level signal input terminal, a low level signal input terminal, a first clock signal terminal, a second clock signal terminal and an output terminal, wherein
the first clock signal terminal inputs a first clock signal to the selection module;
the second clock signal terminal inputs a second clock signal to the selection module;
the selection module couples the high level signal input terminal to the output terminal or disconnects the high level signal input terminal from the output terminal according to the first clock signal, and couples the low level signal input terminal to the output terminal or disconnects the low level signal input terminal from the output terminal according to the second clock signal; and
the selection module couples the high level signal input terminal and the low level signal input terminal alternately to the output terminal, so that the output terminal outputs a target clock signal.

2. The clock signal generating circuit of claim 1, wherein the selection module comprises a first transistor and a second transistor,
a gate of the first transistor is connected with the first clock signal terminal, a source of the first transistor is connected with the high level signal input terminal, and a drain of the first transistor is connected with the output terminal, and
a gate of the second transistor is connected with the second clock signal terminal, a source of the second transistor is connected with the low level signal input terminal, and a drain of the second transistor is connected with the output terminal.

3. The clock signal generating circuit of claim 1, wherein a high level signal inputted from the high level signal input terminal and a low level signal inputted from the low level signal input terminal are direct current signals.

4. The clock signal generating circuit of claim 1, wherein the first clock signal inputted from the first clock signal terminal and the second clock signal inputted from the second clock signal terminal have opposite levels at any time.

5. The clock signal generating circuit of claim 4, wherein the target clock signal has a waveform the same as that of the first clock signal or the second clock signal.

6. A gate driving circuit, comprising the clock signal generating circuit of claim 1, and multiple stages of shift registers.

7. The gate driving circuit of claim 6, wherein the gate driving circuit comprises a plurality of the clock signal generating circuits, each of which is connected to a part of the shift registers.

8. The gate driving circuit of claim 7, wherein the number of the clock signal generating circuits is two, and the two clock signal generating circuits are respectively located at an upper end and a lower end of one side of a display panel on which the shift registers are provided, and are respectively connected with the multiple stages of shift registers in an upper part of the display panel and the multiple stages of shift registers in a lower part of the display panel.

9. The gate driving circuit of claim 6, wherein two ends of every row of pixels on the display panel are connected with one stage of shift registers on corresponding two sides, respectively.

10. The gate driving circuit of claim 9, wherein a plurality of the clock signal generating circuits are provided on each of two opposite sides of the display panel on which the multiple stages of shift registers are provided, and each clock signal generating circuit is connected with a part of the shift registers on a corresponding side.

11. The gate driving circuit of claim 10, wherein the number of the clock signal generating circuits is four, the four clock signal generating circuits are respectively provided in four corners of the display panel, each of the clock signal generating circuits located in the lower part is connected with the multiple stages of shift registers located in a lower part of a corresponding side of the display panel, and each of the clock signal generating circuits located in the upper part is connected with the multiple stages of shift registers located in an upper part of a corresponding side of the display panel.

12. A display panel, comprising the gate driving circuit of claim 6.

13. A display device, comprising the display panel of claim 12.
